(19) United States
(12) Patent Application Publication
(10) Pub. No.: US 2023/0126933 A1
(43) Pub. Date: Apr. 27, 2023

(54) DISPLAY DEVICE INCLUDING SEMICONDUCTOR LIGHT EMITTING DEVICE

(71) Applicants: LG ELECTRONICS INC., Seoul (KR); LG Display Co., Ltd., Seoul (KR)

(72) Inventors: Jaeyong AN, Seoul (KR); Minwoo LEE, Seoul (KR); Yangwoo BYUN, Seoul (KR); Kisu KIM, Seoul (KR)

(73) Assignees: LG Display Co., Ltd., Seoul (KR); LG ELECTRONICS INC., Seoul (KR)

(21) Appl. No.: 17/971,448

(22) Filed: Oct. 21, 2022

(30) Foreign Application Priority Data
Oct. 22, 2021 (KR) PCT/KR2021/014894

(51) Int. Cl. H01L 33/38; H01L 33/62; H01L 25/075

(52) U.S. Cl. CPC H01L 33/382; H01L 33/62; H01L 25/0753

(57) ABSTRACT

A display device can include a first assembly electrode disposed on a substrate, a second assembly electrode disposed above the first assembly electrode, and the first assembly electrode, an insulating layer disposed between the second assembly electrodes, an assembling partition including an assembly hole and disposed on the second assembly electrode, and a semiconductor light emitting device disposed in the assembly hole and electrically connected to the second assembly electrode.

### CROSS-REFERENCE TO RELATED APPLICATION

Pursuant to 35 U.S.C. § 119(a), this application claims the benefit of an earlier filing date of and the right of priority to PCT Application No. PCT/KR2021/014894, filed on Oct. 22, 2021, the entire contents of which are hereby expressly incorporated by reference into the present application.

### BACKGROUND OF THE DISCLOSURE

### 1. Field of the Disclosure

The embodiment relates to a display device including a semiconductor light emitting device.

### 2. Discussion of the Related Art

Large-area displays include liquid crystal displays (LCD), OLED displays, and a micro-LED display and the like.

A micro-LED display is a display using a micro-LED, which is a semiconductor light emitting device having a diameter or cross-sectional area of 100 μm or less, as a display device.

Micro-LED display has excellent performance in many characteristics such as contrast ratio, response speed, color gamut, viewing angle, brightness, resolution, life, luminous efficiency and luminance, because micro-LED, a semiconductor light emitting device, is used as the display device.

In particular, the micro-LED display has the advantage of being able to separate and combine the screens in a modular way, so the size or resolution can be freely adjusted and the flexible display can be implemented.

However, since large micro-LED displays require millions of micro-LEDs, there is a technical problem in that it is difficult to quickly and accurately transfer micro-LEDs to a display panel.

Transfer technologies that have been recently developed include a pick and place process, a laser lift-off method, or a self-assembly method.

Among them, the self-assembly method is a method in which the semiconductor light emitting device finds an assembly position in a fluid by itself, and is advantageous for realization of a large-screen display device.

Recently, although a micro-LED structure suitable for self-assembly has been proposed in U.S. Pat. No. 9,825,202, etc., research on a technology for manufacturing a display through self-assembly of micro-LED is still insufficient.

In particular, in the case of rapidly transferring millions of semiconductor light emitting devices to a large display in the prior art, the transfer speed can be improved, but there is a technical problem in that the transfer defect rate can be increased and the transfer yield is lowered.

In the related art, a self-assembly method using dielectrophoresis (DEP) has been attempted, but the self-assembly rate is low due to the non-uniformity of the DEP force.

Meanwhile, according to an undisclosed internal technology, a DEP force is required for self-assembly. However, due to the difficulty in uniform control of the DEP force, the semiconductor light emitting device is tilted to a different location in the assembly hole during assembly using self-assembly. There is a problem that the phenomenon occurs.

In addition, there is a problem in that the lighting rate is lowered due to the reduction of the electrical contact characteristics in the subsequent electric contact process due to the bias phenomenon of the semiconductor light emitting device.

Therefore, according to the unpublished internal technology, DEP force is required for self-assembly, but when using the DEP force, the semiconductor light emitting device faces a technical contradiction in which electrical contact characteristics are reduced due to the bias phenomenon.

In addition, according to unpublished internal technology, the distribution of DEP force is strongly formed not only inside the assembly hole but also above the assembly hole during self-assembly using the DEP force. Accordingly, there is a problem in that the semiconductor light emitting device to be assembled cannot enter the assembly hall because the semiconductor light emitting device that is not an assembly target blocks the entrance to the assembly hall, resulting in a screen effect.

### SUMMARY OF THE DISCLOSURE

One of the technical problems of the embodiment is to solve the problem of low self-assembly rate due to non-uniformity of DEP force in the self-assembly method using DEP.

In addition, one of the technical problems of the embodiment is to solve the problem that the lighting rate is lowered due to the reduction of electrical contact characteristics between the electrodes of the self-assembled light emitting device and a panel electrode.

One of the technical problems of the embodiment is to solve the problem of a screen effect that a distribution of DEP force is strongly formed not only inside the assembly hole but also on the upper side of the assembly hole, so a semiconductor light emitting device that is not an assembly target can block the entrance to the assembly hole and prevent the semiconductor light emitting device to be assembled from entering the assembly hall.

The technical problems of the embodiment are not limited to those described in this item, and include those that can be grasped throughout the specification.

A display device including a semiconductor light emitting device according to an embodiment includes a substrate, a first assembly electrode disposed on the substrate, a second assembly electrode disposed above the first assembly electrode, and the first assembly electrode an insulating layer disposed between the assembly electrode and the second assembly electrode, and an assembling barrier wall disposed on the second assembly electrode and including an assembly hole, and a semiconductor light emitting device disposed in the assembly hole, and electrically connecting the second assembly electrode.

The second assembly electrode can have an electrode hole in a region overlapping the semiconductor light emitting device and a portion of the insulating layer can be exposed.

A size of the electrode hole can be less than a size of the semiconductor light emitting device.

AC power can be applied to the first assembled electrode, and the assembled electrode can be grounded.

The first assembly electrode can include a first main electrode and a first protrusion electrode extended from the first main electrode.

The second assembly electrode can include a second main electrode that is disposed parallel in a longitudinal direction of the first main electrode, and a second protrusion electrode extended from the second main electrode.

The second protrusion electrode can protrude toward the first protrusion electrode.

The second protrusion electrode can overlap the first protrusion electrode between upper and lower sides.

The second protrusion electrode of the second assembly electrode can include the electrode hole in a region overlapping the semiconductor light emitting device, so a portion of the insulating layer can be exposed.

The first assembly electrode can include a first center electrode overlapping the inside of the electrode hole of the second protrusion electrode on the upper and lower portions.

The second assembly electrode can include a first bridge electrode and a second bridge electrode disposed inside the electrode hole and connected to each other.

The semiconductor light emitting device and the display device including the same according to the embodiment have a technical effect that can solve the problem of low self-assembly rate due to non-uniformity of DEP force in the self-assembly method using dielectrophoresis (DEP).

For example, in the embodiment, as the assembly electrode is symmetrically disposed between the top and bottom, a uniform Dep force is distributed in the center of the assembly hole, and there is a technical effect of improving the assembly rate.

In addition, according to the embodiment, as the electrical contact area between the electrode of the semiconductor light emitting device and the assembly electrode functioning as the panel electrode is increased, the electrical contact characteristic is improved and the lighting rate is significantly increased.

In addition, according to the embodiment, as the V+/V− signal is applied to the first assembled electrode 210, which is the lower electrode, and the second assembled electrode 220, which is the upper electrode, is grounded, the voltage drop is prevented. Accordingly, there is a special technical effect that can maintain a high assembly force.

In addition, according to the embodiment, the distribution of the DEP force can be strongly and uniformly distributed at the inner center of the assembly hole through the electric field shielding on the upper side of the assembly hole, and the distribution strength can be controlled weakly on the upper side of the assembly hole. Through this, the semiconductor light emitting device that is not the object of assembly is prevented from being located on the upper side of the assembly hole, there is a special technical effect that can solve the problem of the screening effect that the entrance to the assembly hall cannot be blocked and the semiconductor light emitting device to be assembled does not enter the assembly hall.

In addition, according to the embodiment, there is a technical effect capable of realizing an ultra-high resolution by three-dimensionally disposing the first assembly electrode and the second assembly electrode between the top and bottom.

In addition, according to the embodiment, by disposing to overlap between the first protrusion electrode of the first assembled electrode and the second protrusion electrode of the second assembled electrode, there is a complex technical effect that can improve the assembly of the semiconductor light emitting device by allowing the DEP force to be distributed intensively at the center of the assembly hole between the first protrusion electrode and the second protrusion electrode.

The technical effects of the embodiments are not limited to those described in this item, and include those identified from the description of the invention

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is an exemplary view of a living room of a house in which a display device according to an embodiment is disposed.

FIG. 2 is a block diagram schematically showing a display device according to an embodiment.

FIG. 3 is a circuit diagram showing an example of a pixel according to an embodiment.

FIG. 4 is an enlarged view of a first panel area in the display device of FIG. 1

FIG. 5 is a cross-sectional view taken along line B1-B2 of area A2 in FIG. 4.

FIG. 6 is an exemplary view in which the light emitting device according to the embodiment is assembled on a substrate by a self-assembly method.

FIG. 7 is a partially enlarged view of area A3 of FIG. 6;

FIGS. 8A to 8B is an example of self-assembly in the display device according to the internal technology.

FIG. 8C is a self-assembly picture in the display device according to the internal technology.

FIG. 8D is a view showing a tilt phenomenon that occurs during self-assembly to the internal technology.

FIG. 8E is a FIB (focused ion beam) photograph of a light emitting device (chip) and bonding metal in a display panel according to an internal technology.

FIG. 8F is lighting data in a display panel in the internal technology.

FIG. 9 is a cross-sectional view of a display device including a semiconductor light emitting device according to a first embodiment.

FIGS. 10A to 10C are electric field distribution diagrams in the assembly of a display device having a semiconductor light emitting device according to a comparative example and an embodiment.

FIGS. 11A to 11C are first exemplary views of an assembly electrode of a display device 301 including a semiconductor light emitting device according to the first embodiment.

FIGS. 12A to 12C are second exemplary views of assembly electrodes of the display device 301 including the semiconductor light emitting device according to the first embodiment.

FIGS. 13A to 13C are diagrams illustrating an assembling process of the semiconductor light emitting device using the display device including the semiconductor light emitting device according to the first embodiment.

FIG. 14 is a cross-sectional view of a display device including a semiconductor light emitting device according to a second embodiment.

FIGS. 15A to 15C are exemplary views of assembled electrodes of a display device including a semiconductor light emitting device according to a second embodiment.

FIGS. 16A to 16B are diagrams illustrating an assembling process of the semiconductor light emitting device using the display device including the semiconductor light emitting device according to the second embodiment.

FIG. 17A is a first cross-sectional view of a display device including a semiconductor light emitting device according to a third embodiment.

FIG. 17B is a second cross-sectional view of a display device including a semiconductor light emitting device according to a third embodiment.

FIGS. 18A to 18C are exemplary views of an assembly electrode of a display device including a semiconductor light emitting device according to a third embodiment.

FIGS. 19A to 19B are views illustrating an assembling process of the semiconductor light emitting device using the display device including the semiconductor light emitting device according to the embodiment.

### DETAILED DESCRIPTION OF THE DISCLOSURE

Hereinafter, embodiments disclosed in the present specification will be described in detail with reference to the accompanying drawings. The suffixes ‘module’ and ‘part’ for components used in the following description are given or mixed in consideration of ease of specification, and do not have a meaning or role distinct from each other by themselves. In addition, the accompanying drawings are provided for easy understanding of the embodiments disclosed in the present specification, and the technical ideas disclosed in the present specification are not limited by the accompanying drawings. Further, when an element, such as a layer, region, or substrate, is referred to as being ‘on’ another component, this includes that it is directly on the other element or there can be other intermediate elements in between.

The display device described in this specification includes a digital TV, a mobile phone, a smart phone, a laptop computer, a digital broadcasting terminal, a personal digital assistant (PDA), a portable multimedia player (PMP), a navigation, a Slate PC, a Tablet PC, an Ultra-Book, a desktop computer, and the like. However, the configuration according to the embodiment described in the present specification can be applied to a display capable device even if it is a new product form to be developed later.

Hereinafter, a light emitting device and a display device including the same according to an embodiment will be described.

Hereinafter, a semiconductor light emitting device and a display device including the same according to an embodiment will be described.

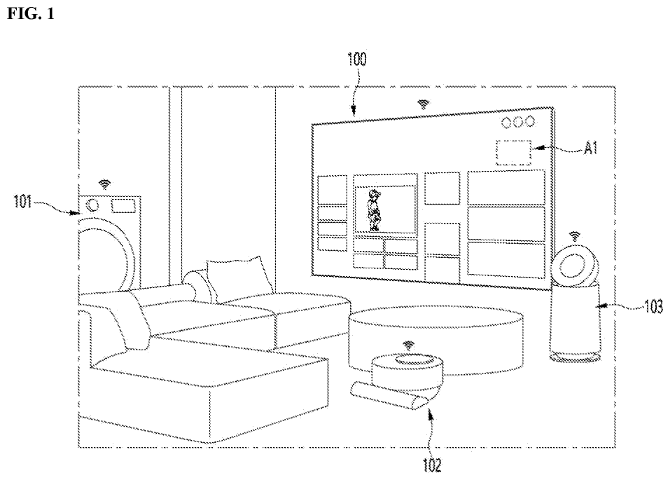

FIG. 1 shows a living room of a house in which the display device 100 according to the embodiment is disposed.

The display device 100 of the embodiment can display the status of various electronic products such as the washing machine 101, the robot cleaner 102, and the air purifier 103, and communicate with each electronic product based on IOT. Further, each electronic product can be controlled based on the user's setting data.

The display device 100 according to the embodiment can include a flexible display fabricated on a thin and flexible substrate. The flexible display can be bent or rolled like paper while maintaining the characteristics of a conventional flat panel display.

In the flexible display, visual information can be implemented by independently controlling the light emission of unit pixels arranged in a matrix form. A unit pixel means a minimum unit for realizing one color. The unit pixel of the flexible display can be implemented by a light emitting device. In an embodiment, the light emitting device can be a Micro-LED or a Nano-LED, but is not limited thereto.

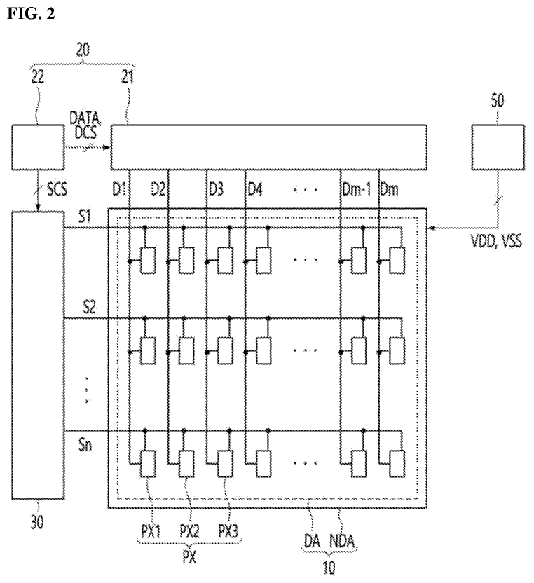

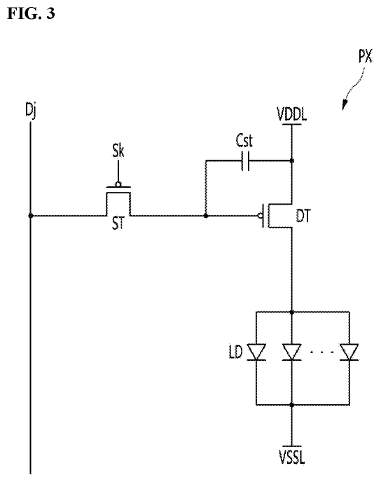

Next, FIG. 2 is a block diagram schematically showing a display device according to an embodiment, and FIG. 3 is a circuit diagram showing an example of a pixel according to an embodiment.

Referring to FIGS. 2 and 3, the display device according to the embodiment can include a display panel 10, a driving circuit 20, a scan driving unit 30, and a power supply circuit 50. All the components of the display device according to all embodiments are operationally coupled and configured.

The display device 100 according to the embodiment can drive the light emitting device in an active matrix (AM) method or a passive matrix (PM) method.

The driving circuit 20 can include a data driver 21 and a timing controller 22.

The display panel 10 can be divided into a display area DA and a non-display area NDA disposed around the display area DA. The display area DA is an area in which pixels PX are formed to display an image. The display panel 10 includes data lines (D1 to Dm, m is an integer greater than or equal to 2), scan lines crossing the data lines D1 to Dm (S1 to Sn, n is an integer greater than or equal to 2), the high-potential voltage line supplied with the high-voltage, the low-potential voltage line supplied with the low-potential voltage, and the pixels PX connected to the data lines D1 to Dm and the scan lines S1 to Sn can be included.

Each of the pixels PX can include a first sub-pixel PX1, a second sub-pixel PX2, and a third sub-pixel PX3. The first sub-pixel PX1 emits a first color light of a first wavelength, the second sub-pixel PX2 emits a second color light of a second wavelength, and the third sub-pixel PX3 can emits a third color light of a wavelength. The first color light can be red light, the second color light can be green light, and the third color light can be blue light, but is not limited thereto. Further, although it is illustrated that each of the pixels PX includes three sub-pixels in FIG. 2, the present invention is not limited thereto. For example, each of the pixels PX can include four or more sub-pixels.

Each of the first sub-pixel PX1, the second sub-pixel PX2, and the third sub-pixel PX3 is at least one of the data lines D1 to Dm, at least one of the scan lines S1 to Sn, and can be connected to a high potential voltage line. As shown in FIG. 3, the first sub-pixel PX1 can include a plurality of transistors and at least one capacitor Cst for supplying current to the light emitting devices LD and the light emitting devices LDs.

Each of the first subpixel PX1, the second subpixel PX2, and the third subpixel PX3 can include one light emitting element LD and at least one capacitor Cst.

Each of the light emitting devices LD can be a semiconductor light emitting diode including a first electrode, a plurality of conductivity type semiconductor layers, and a second electrode. Here, the first electrode can be an anode electrode and the second electrode can be a cathode electrode, but the present invention is not limited thereto.

Referring to FIG. 3, the plurality of transistors includes a driving transistor DT for supplying current to the light emitting devices LD, and a scan transistor ST for supplying a data voltage to the gate electrode of the driving transistor DT. The driving transistor DT can include a gate electrode connected to a source electrode of the scan transistor ST, a source electrode connected to a high potential voltage line to which a high potential voltage is applied, and a drain connected to first electrodes of the light emitting devices LD. The scan transistor ST has a gate electrode connected to the scan line Sk, where k is an integer satisfying 1≤k≤n, a source electrode connected to the gate electrode of the driving transistor DT, and data lines Dj and j are and a drain electrode connected to an integer satisfying 1≤j≤m).

The capacitor Cst is formed between the gate electrode and the source electrode of the driving transistor DT. The storage capacitor Cst can charge a difference between the gate voltage and the source voltage of the driving transistor DT.

The driving transistor DT and the scan transistor ST can be formed of a thin film transistor. In addition, although the driving transistor DT and the scan transistor ST have been mainly described in FIG. 3 as being formed of a P-type MOSFET (Metal Oxide Semiconductor Field Effect Transistor), the present invention is not limited thereto. The driving transistor DT and the scan transistor ST can be formed of an N-type MOSFET. In this case, the positions of the source electrode and the drain electrode of each of the driving transistor DT and the scan transistor ST can be changed.

Further, in FIG. 3, each of the first sub-pixel PX1, the second sub-pixel PX2, and the third sub-pixel PX3 includes one driving transistor DT, one scan transistor ST, and 2T1C (2 Transistor-1 capacitor) having a capacitor has been illustrated, but the present invention is not limited thereto. Each of the first sub-pixel PX1, the second sub-pixel PX2, and the third sub-pixel PX3 can include a plurality of scan transistors ST and a plurality of capacitors Cst.

Referring back to FIG. 2, the driving circuit 20 outputs signals and voltages for driving the display panel 10. To this end, the driving circuit 20 can include a data driver 21 and a timing controller 22.

The data driver 21 receives digital video data DATA and a source control signal DCS from the timing controller 22. The data driver 21 converts the digital video data DATA into analog data voltages according to the source control signal DCS and supplies them to the data lines D1 to Dm of the display panel 10.

The timing controller 22 receives digital video data DATA and timing signals from the host system. The timing signals can include a vertical sync signal, a horizontal sync signal, a data enable signal, and a dot clock. The host system can be an application processor of a smartphone or tablet PC, a monitor, a system-on-chip of a TV, or the like.

The scan driver 30 receives the scan control signal SCS from the timing controller 22. The scan driver 30 generates scan signals according to the scan control signal SCS and supplies them to the scan lines S1 to Sn of the display panel 10. The scan driver 30 can include a plurality of transistors and can be formed in the non-display area NDA of the display panel 10. Alternatively, the scan driver 30 can be formed of an integrated circuit, and in this case, can be mounted on a gate flexible film attached to the other side of the display panel 10.

The power supply circuit 50 generates a high potential voltage (VDD) and a low potential voltage (VSS) for driving the light emitting elements (LD) of the display panel 10 from the main power display panel (10). And they can be supplied to the high potential voltage line and the low potential voltage line. Further, the power supply circuit 50 can generate and supply driving voltages for driving the driving circuit 20 and the scan driving unit 30 from the main power.

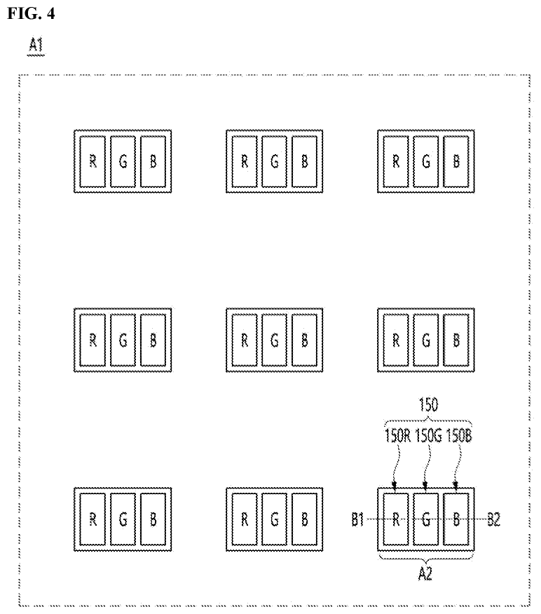

Next, FIG. 4 is an enlarged view of the first panel area A1 in the display device of FIG. 1.

Referring to FIG. 4, the display device 100 according to the embodiment can be manufactured by mechanically and electrically connecting a plurality of panel areas such as the first panel area A1 by tiling.

The first panel area A1 can include a plurality of light emitting devices 150 arranged for each unit pixel (PX in FIG. 2).

For example, the unit pixel PX can include a first sub-pixel PX1, a second sub-pixel PX2, and a third sub-pixel PX3. For example, the plurality of red light-emitting devices 150R are disposed in the first sub-pixel PX1, the plurality of green light-emitting devices 150G are disposed in the second sub-pixel PX2, and the plurality of blue light-emitting devices 150B are disposed in the second sub-pixel PX3. The unit pixel PX can further include a fourth sub-pixel in which a light emitting device is not disposed, but is not limited thereto. Meanwhile, the light emitting device 150 can be a semiconductor light emitting device.

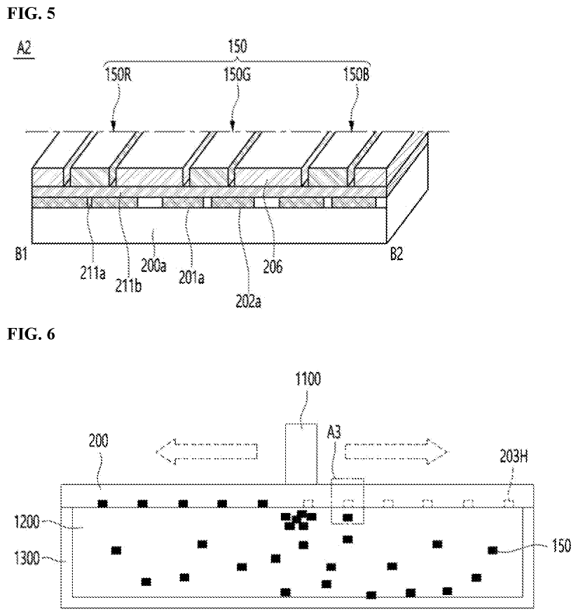

Next, FIG. 5 is a cross-sectional view taken along line B1-B2 of area A2 of FIG. 4.

Referring to FIG. 5, the display device 100 of the embodiment includes a substrate 200a, wirings 201a and 202a spaced apart from each other, a first insulating layer 211a, a second insulating layer 211b, and a third insulating layer 260 and a plurality of light emitting devices 150.

The wiring can include a first wiring 201a and a second wiring 202a spaced apart from each other. The first wiring 201a and the second wiring 202a can function as a panel wiring for applying power to the light emitting device 150 in the panel. In the case of self-assembly of the light emitting device 150, they can function as an assembly electrode to generate a dielectrophoretic force for assembly.

The wirings 201a and 202a can be formed of a transparent electrode (ITO) or include a metal material having excellent electrical conductivity. For example, the wirings 201a and 202a can be formed at least one of titanium (Ti), chromium (Cr), nickel (Ni), aluminum (Al), platinum (Pt), gold (Au), tungsten (W), molybdenum (Mo) or an alloy thereof.

A first insulating layer 211a can be disposed between the first wiring 201a and the second wiring 202a, and a second insulating layer 211b can be disposed on the first wiring 201a and the second wiring 202a. The first insulating layer 211a and the second insulating layer 211b can be an oxide film, a nitride film, or the like, but are not limited thereto.

The light emitting device 150 can include a red-light emitting device 150R, a green light emitting device 150G, and a blue light emitting device 150B to form a sub-pixel, respectively. However, the present invention is not limited thereto, and red and green can be implemented by providing a red phosphor and a green phosphor, respectively.

The substrate 200a can be formed of glass or polyimide. Further, the substrate 200a can include a flexible material such as polyethylene naphthalate (PEN) or polyethylene terephthalate (PET). In addition, the substrate 200 can be made of a transparent material, but is not limited thereto. The substrate 200a can function as a support substrate in the panel, and can function as a substrate for assembly when self-assembling the light emitting device.

The third insulating layer 206 can include an insulating and flexible material such as polyimide, PEN, PET, etc., and can be integrally formed with the substrate 200a to form one substrate.

The third insulating layer 206 can be a conductive adhesive layer having adhesiveness and conductivity, and the conductive adhesive layer can be flexible to enable a flexible function of the display device. For example, the third insulating layer 206 can be an anisotropy conductive film (ACF) or a conductive adhesive layer such as an anisotropic conductive medium or a solution containing conductive particles. The conductive adhesive layer can be a layer that is electrically conductive in a direction perpendicular to the thickness but electrically insulating in a direction horizontal to the thickness.

The gap between the first and second wirings 201a and 202a is formed to be smaller than the width of the light emitting device 150 and the width of the assembly hole 203H. Accordingly, the assembly position of the light emitting device 150 using the electric field can be precisely fixed.

A third insulating layer 206 is formed on the first and second wirings 201a and 202a to protect the first and second wirings 201a and 202a from the fluid 1200, It is possible to prevent leakage of current flowing through the first and second wirings 201a and 202a. The third insulating layer 206 can be formed of a single layer or multiple layers of an inorganic insulator such as silica or alumina or an organic insulator.

In addition, the third insulating layer 206 can include an insulating and flexible material such as polyimide, PEN, PET, etc., and can be formed integrally with the substrate 200 to form a single substrate.

The third insulating layer 206 has a barrier wall, and an assembly hole layer 206 can include an assembly hole 203H through which the light emitting device 150 is inserted (refer to FIG. 6). Accordingly, during self-assembly, the light emitting device 150 can be easily inserted into the assembly hole 203H of the third insulating layer 206. The assembly hole 203H can be referred to as an insertion hole, a fixing hole, an alignment hole, or the like.

The assembly hole 203H can have a shape and a size corresponding to the shape of the light emitting device 150 to be assembled at a corresponding position. Accordingly, it is possible to prevent assembling other light emitting devices or assembling a plurality of light emitting devices in the assembly hole 203H.

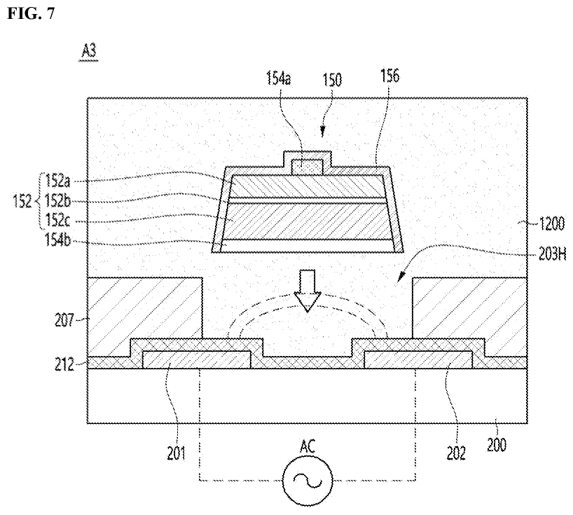

Next, FIG. 6 is a view showing an example in which a light emitting device according to an embodiment is assembled on a substrate by a self-assembly method, and FIG. 7 is a partially enlarged view of area A3 of FIG. 6 And FIG. 7 is a view of a state in which area A3 is rotated by 180 degrees for convenience of explanation.

An example in which the semiconductor light emitting device according to the embodiment is assembled in a display panel by a self-assembly method using an electromagnetic field will be described with reference to FIGS. 6 and 7.

The assembly substrate 200 to be described later can also function as the panel substrate 200a in the display device after assembly of the light emitting device, but the embodiment is not limited thereto.

Referring to FIG. 6, the semiconductor light emitting device 150 can be put into a chamber 1300 filled with a fluid 1200, and the semiconductor light emitting device 150 can move to the assembly substrate 200 by the magnetic field generated from the assembly apparatus 1100. In this case, the light emitting device 150 adjacent to the assembly hole 203H of the assembly substrate 200 can be assembled in the assembly hole 230 by a dielectrophoretic force by an electric field of the assembly electrodes.

The fluid 1200 can be water such as ultrapure water, but is not limited thereto. A chamber can be referred to as a water bath, container, vessel, or the like.

After the semiconductor light emitting device 150 is put into the chamber 1300, the assembly substrate 200 can be disposed on the chamber 1300. According to an embodiment, the assembly substrate 200 can be introduced into the chamber 1300.

Referring to FIG. 7, the semiconductor light emitting device 150 can be implemented as a vertical semiconductor light emitting device as shown, but is not limited thereto, and a horizontal light emitting device can be employed.

The semiconductor light emitting device 150 can include a magnetic layer having a magnetic material. The magnetic layer can include a magnetic metal such as nickel (Ni). Since the semiconductor light emitting device 150 injected into the fluid includes a magnetic layer, it can move to the assembly substrate 200 by the magnetic field generated from the assembly apparatus 1100. The magnetic layer can be disposed on the upper side, the lower side, or both sides of the light emitting device.

The semiconductor light emitting device 150 can include a passivation layer 156 surrounding the top and side surfaces. The passivation layer 156 can be formed by PECVD, LPCVD, sputtering deposition, or the like, inorganic insulator such as silica or alumina. In addition, the passivation layer 156 can be formed through a method of spin coating an organic material such as a photoresist or a polymer material.

The semiconductor light emitting device 150 can include a first conductivity type semiconductor layer 152a, a second conductivity type semiconductor layer 152c, and an active layer 152b disposed therebetween. The first conductivity-type semiconductor layer 152a can be an n-type semiconductor layer, and the second conductivity type semiconductor layer 152c can be a p-type semiconductor layer, but is not limited thereto.

A first electrode layer 154a can be disposed on the first conductivity type semiconductor layer 152a, and a second electrode layer 154b can be disposed on the second conductivity type semiconductor layer 152c. To this end, a partial region of the first conductivity type semiconductor layer 152a or the second conductivity type semiconductor layer 152c can be exposed to the outside. Accordingly, after the semiconductor light emitting device 150 is assembled on the assembly substrate 200, a portion of the passivation layer 156 can be etched in the manufacturing process of the display device.

The assembly substrate 200 can include a pair of first assembly electrodes 201 and second assembly electrodes 202 corresponding to each of the semiconductor light emitting devices 150 to be assembled. The first assembly electrode 201 and the second assembly electrode 202 can be formed by stacking a single metal, a metal alloy, or a metal oxide in multiple layers. For example, the first assembled electrode 201 and the second assembled electrode 202 can be formed including at least one of Cu, Ag, Ni, Cr, Ti, Al, Rh, Pd, Ir, Ru, Mg, Zn, Pt, Au or Hf, but it is not limited thereto.

In addition, the first assembly electrode 201 and the second assembly electrode 202 can be formed including at least one of indium tin oxide (ITO), indium zinc oxide (IZO), indium zinc tin oxide (IZTO), indium aluminum zinc oxide (IAZO), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al—Ga ZnO), IGZO (In—Ga ZnO), ZnO, IrOx, RuOx, NiO, RuOx/ITO,

The first assembled electrode 201, the second assembled electrode 202 emits an electric field as an AC voltage is applied, the semiconductor light emitting device 150 inserted into the assembly hole 203H can be fixed by dielectrophoretic force. A distance between the first assembly electrode 201 and the second assembly electrode 202 can be smaller than a width of the semiconductor light emitting device 150 and a width of the assembly hole 203H, the assembly position of the semiconductor light emitting device 150 using the electric field can be more precisely fixed.

An insulating layer 212 is formed on the first assembly electrode 201 and the second assembly electrode 202 to protect the first assembly electrode 201 and the second assembly electrode 202 from the fluid 1200 and leakage of current flowing through the first assembled electrode 201 and the second assembled electrode 202 can be prevented. For example, the insulating layer 212 can be formed of a single layer or multiple layers of an inorganic insulator such as silica or alumina or an organic insulator. The insulating layer 212 can have a minimum thickness to prevent damage to the first assembly electrode 201 and the second assembly electrode 202 when the semiconductor light emitting device 150 is assembled, and it can have a maximum thickness for the semiconductor light emitting device 150 being stably assembled.

A barrier wall 207 can be formed on the insulating layer 212. A portion of the partition wall 207 can be positioned on the first assembly electrode 201 and the second assembly electrode 202, and the remaining region can be positioned on the assembly substrate 200.

On the other hand, when the assembly substrate 200 is manufactured, a portion of the barrier walls formed on the entire upper portion of the insulating layer 212 is removed, an assembly hole 203H in which each of the semiconductor light emitting devices 150 is coupled and assembled to the assembly substrate 200 can be formed.

An assembly hole 203H to which the semiconductor light emitting devices 150 are coupled is formed in the assembly substrate 200, and a surface on which the assembly hole 203H is formed can be in contact with the fluid 1200. The assembly hole 203H can guide an accurate assembly position of the semiconductor light emitting device 150.

Meanwhile, the assembly hole 203H can have a shape and a size corresponding to the shape of the semiconductor light emitting device 150 to be assembled at a corresponding position. Accordingly, it is possible to prevent assembling other semiconductor light emitting devices or assembling a plurality of semiconductor light emitting devices in the assembly hole 203H.

Referring back to 6, after the assembly substrate 200 is disposed in the chamber, the assembly apparatus 1100 for applying a magnetic field can move along the assembly substrate 200. The assembly device 1100 can be a permanent magnet or an electromagnet.

The assembly apparatus 1100 can move while in contact with the assembly substrate 200 in order to maximize the area applied by the magnetic field into the fluid 1200. According to an embodiment, the assembling apparatus 1100 can include a plurality of magnetic materials or a magnetic material having a size corresponding to that of the assembly substrate 200. In this case, the moving distance of the assembly apparatus 1100 can be limited within a predetermined range.

The semiconductor light emitting device 150 in the chamber 1300 can move toward the assembly apparatus 1100 and the assembly substrate 200 by the magnetic field generated by the assembly apparatus 1100.

Referring to FIG. 7, the semiconductor light emitting device 150 is moving toward the assembly device 1100, It can enter and be fixed into the assembly hole 203H by a dielectrophoretic force (DEP force) formed by the electric field of the assembly electrode of the assembly substrate.

Specifically, the first and second assembly wirings 201 and 202 can form an electric field by an AC power source, and a dielectrophoretic force can be formed between the assembly wirings 201 and 202 by this electric field. The semiconductor light emitting device 150 can be fixed to the assembly hole 203H on the assembly substrate 200 by this dielectrophoretic force.

At this time, a solder layer is formed between the light emitting device 150 and the assembly electrode assembled on the assembly hole 203H of the assembly substrate 200 to can improve the bonding force of the light emitting device 150.

In addition, a molding layer can be formed in the assembly hole 203H of the assembly substrate 200 after assembly. The molding layer can be a transparent resin or a resin including a reflective material and a scattering material.

By the self-assembly method using the electromagnetic field described above, the time required for each of the semiconductor light emitting devices to be assembled on the substrate can be rapidly reduced, so a large-area high-pixel display can be implemented more quickly and economically.

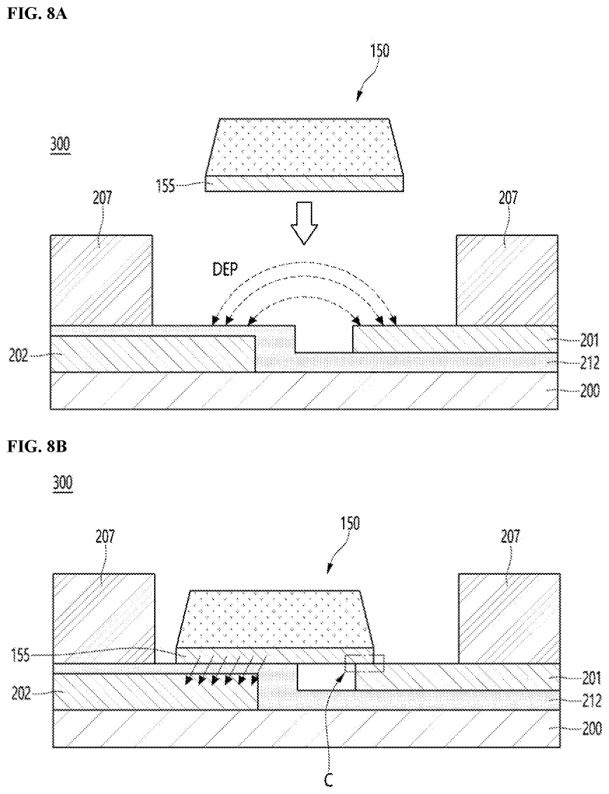

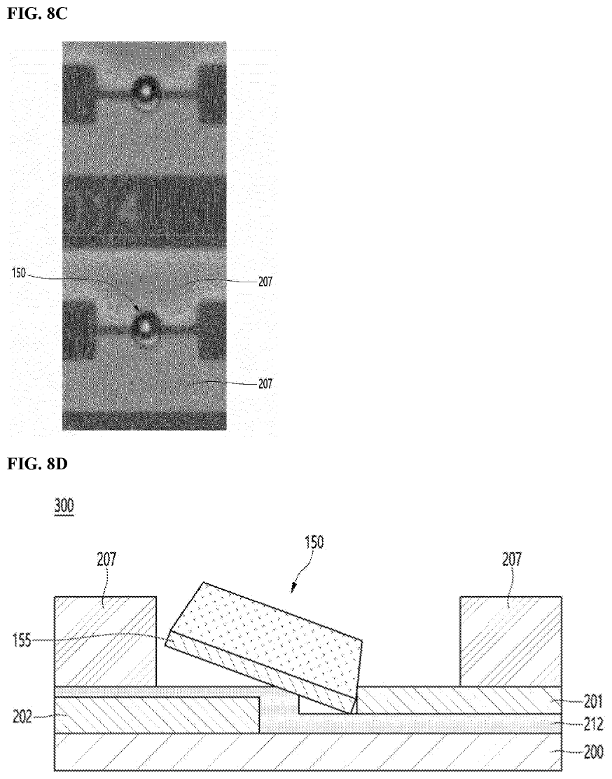

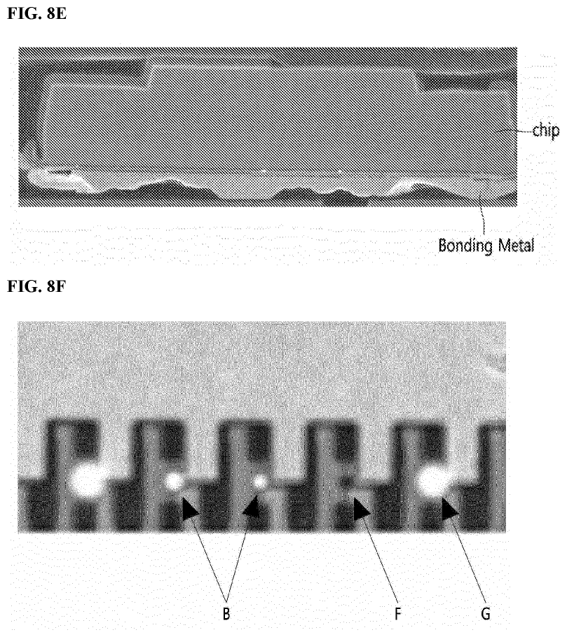

Next, FIGS. 8A to 8B are diagrams illustrating self-assembly in the display device 300 according to the internal technology, and FIG. 8C is a picture of self-assembly in the display device according to the internal technology.

In the display device 300 according to the internal technology, either the first assembly electrode 201 or the second assembly electrode 202 is brought into contact with the bonding metal 155 of the semiconductor light emitting device 150 through a bonding process.

However, in order to solve the problem that the bonding area is also reduced as the semiconductor light emitting device 150 is miniaturized, as shown in FIGS. 8A to 8B, a method of omitting the existing Vdd line and completely opening its role to one side of the electrode wiring is used.

However, when this method is used, the semiconductor light emitting device 150 drawn to the first assembly electrode 201 by DEP in the fluid comes into contact with the first assembly electrode 201 and becomes conductive. Accordingly, the electric field force is concentrated on the second assembled electrode 202 that is not opened by the insulating layer 212, and as a result, there is a problem in that the assembly is biased in one direction.

Referring to FIGS. 8B and 8C, the contact area C between the bonding metal 155 of the semiconductor light emitting device 150 and the first assembly electrode 201 functioning as a panel electrode is very small, so poor contact can be occurred.

For example, according to the undisclosed internal technology, even though DEP Force is required for self-assembly, there is a problem in that the semiconductor light emitting device tilts to a different place in the assembly hole during assembly using self-assembly due to the difficulty of uniform control of the DEP force.

In addition, due to this tilting phenomenon of the semiconductor light emitting device, electrical contact characteristics are lowered in the subsequent electrical contact process, resulting in a defective lighting rate and a lower yield.

Therefore, according to the unpublished internal technology, DEP Force is required for self-assembly, but when using the DEP Force, the semiconductor light emitting device faces a technical contradiction in which electrical contact

Next, FIG. 8D is a view showing a tilt phenomenon that can occur during self-assembly according to the internal technology.

According to internal description, an insulating layer 212 is disposed on the first and second assembly electrodes 201 and 202 on the assembly substrate 200, self-assembly by the dielectrophoretic force of the semiconductor light emitting device 150 is performed in the assembly hole H set by the assembly and assembly barrier wall 207. However, according to internal technology, the electric field force is concentrated to the second assembly electrode 202, and as a result, there is a problem in that the assembly is biased in one direction, and thus the problem of self-assembly is not properly performed and the problem of tilting in the assembly hole (H) has been studied.

Further, FIG. 8E is a FIB (focused ion beam) photograph of a light emitting device (chip) and bonding metal in a display panel according to an internal technology, and FIG. 8F is lighting data in a display panel in an internal technology.

As shown in FIG. 8E, in the semiconductor light emitting device according to the internal technology, the surface morphology of the back bonding metal is not good, and the contact characteristic between the back bonding metal of the light emitting device and the panel wiring is not good, so lighting failure occurs.

In addition, according to the internal technology, the back bonding metal is in contact with the assembled electrode, but electrical contact failure occurs due to the surface non-uniformity of the bonding metal.

For example, FIG. 8F is lighting data in a display panel according to an internal technology.

According to the internal technology, in the self-assembly method, weak lighting (B: Bad) or non-lighting (F: Fail) occurs due to a biasing phenomenon due to non-uniformity of DEP force or due to a defect in the surface properties of the back bonding metal and good lighting (G: Good) is not achieved, and the lighting rate was studied at the level of 93.94%

In the internal technology, materials such as Ti, Cu, Pt, Ag, Au can be used for the electrode layer of the light emitting device, when a bonding metal made of a material such as Sn or In is formed on the electrode layer made of such as materials, the surface becomes bumpy due to agglomeration or the like.

On the other hand, in the internal technology, the deposition rate was increased to improve the surface properties of the bonding metal, but even if the aggregation phenomenon was partially alleviated, another problem was found that the grain size decreased as the deposition rate increased and the contact force decreased, the problem of improving the surface properties of the bonding metal was not easy.

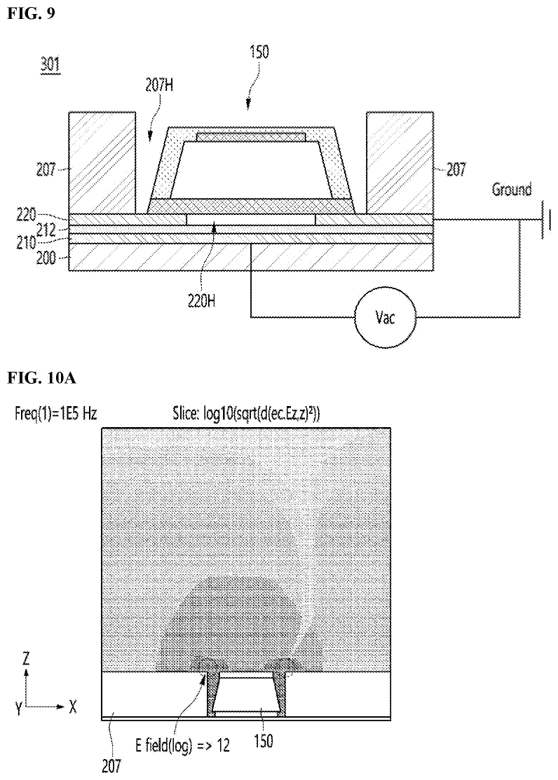

Next, with reference to FIGS. 9 to 13C, a display device 301 having a semiconductor light emitting device according to a first embodiment (hereinafter, ‘first embodiment’ is abbreviated as ‘embodiment’) will be explained.

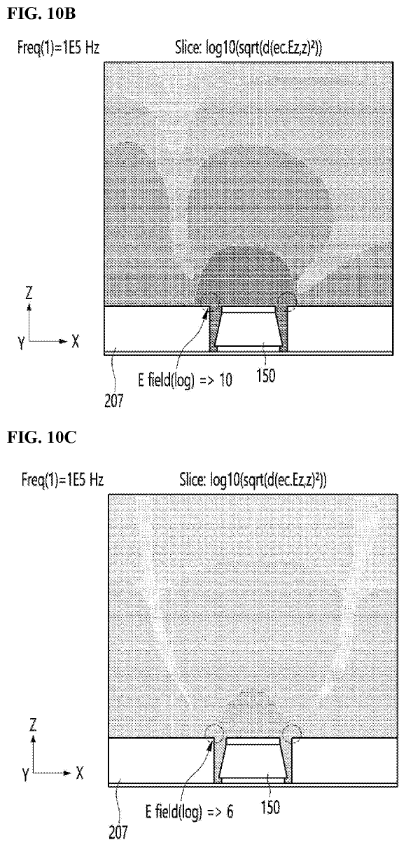

FIG. 9 is a cross-sectional view of a display device 301 including a semiconductor light emitting device according to an embodiment. FIGS. 10A to 10C are electric field distribution diagrams in assembling a display device 301 including a semiconductor light emitting device according to a comparative example and an embodiment.

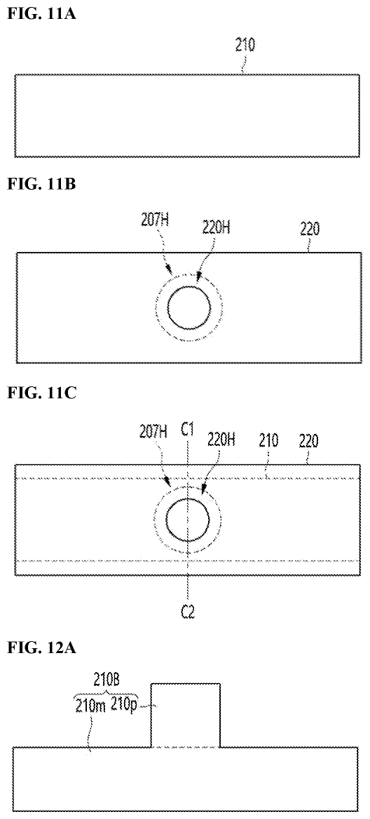

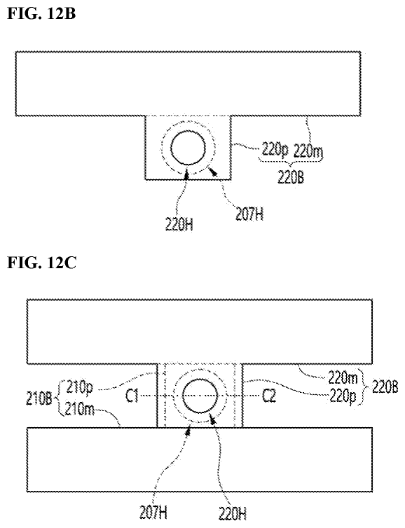

FIGS. 11A to 11C are first exemplary views of an assembly electrode of a display device 301 including a semiconductor light emitting device according to an embodiment. FIGS. 12A to 12C are second exemplary views of assembled electrodes of a display device 301 including a semiconductor light emitting device according to an embodiment.

In the first internal technology, in the horizontal assembly electrode structure in which the first assembly electrode and the second assembly electrode are horizontally disposed at the same height (refer to FIG. 7), an insulating film is formed on the electrode. Accordingly, according to the first internal technology, when the semiconductor light emitting device is a vertical LED, it is difficult to electrically connect the lower electrode of the LED and the assembled electrode without a separate process. On the other hand, in order to emit light through the lower electrode of the vertical LED, a signal applying electrode must be formed between the horizontal assembly electrode structures. As the LED chip becomes smaller, the gap between the horizontally assembled electrode structures becomes narrower, so it is difficult to form the signal applying electrode.

On the other hand, in the vertical asymmetric electrode structure (refer to FIG. 8A) according to the second internal technology, the LED light emitting signal is applied due to the bonding of the first assembly electrode 201 on the insulating film and the bonding metal 155 of the semiconductor light emitting device. On the other hand, since the assembled electrode structure is asymmetrical, the electric field distribution is also asymmetrically formed, which can be biased toward one side when assembling a semiconductor light emitting device, since the bonding area between the first assembly electrode 201 and the bonding metal 155 on the insulating layer is small, as the size of the light emitting chip becomes smaller, it is difficult to apply a signal (refer to FIGS. 8B to 8F).

One of the technical problems of the embodiment is to solve the problem of low self-assembly rate due to non-uniformity of DEP force in the self-assembly method using dielectrophoresis (DEP).

In addition, one of the technical problems of the embodiment is to solve the problem that the lighting rate is lowered due to the lowering of electrical contact characteristics between the electrodes of the self-assembled light emitting device and a panel electrode.

In addition, one of the technical problems of the embodiment is that the distribution of DEP Force is strongly formed not only inside the assembly hole but also on the upper side of the assembly hole. The embodiment is to solve the problem of a screening effect in which a semiconductor light emitting device to be assembled cannot enter an assembly hall because a semiconductor light emitting device that is not an assembly target blocks the entrance to the assembly hall.

FIG. 9 is a cross-sectional view of a display device 301 including a semiconductor light emitting device according to a first embodiment, and the first embodiment will be abbreviated as an embodiment.

Referring to FIG. 9, a display device 301 having a semiconductor light emitting device according to an embodiment includes a substrate 200, a first assembly electrode 210 disposed on the substrate 200, a second assembly electrode 220 disposed above the first assembly electrode 210, the first assembly electrode an insulating layer 212 disposed between 210 and the second assembly electrode 220, and an assembly hole 207H, and an assembly barrier wall 207 disposed on the second assembly electrode 220, and a semiconductor light emitting device 150 disposed in the assembly hole 207H and electrically connected to the second assembly electrode 220. The second assembly electrode 220 can have an electrode hole 220H in a region overlapping the semiconductor light emitting device 150, so a portion of the insulating layer 212 can be exposed.

The size of the electrode hole 220H can be smaller than the size of the semiconductor light emitting device 150. The size of the electrode hole 220H can be a diameter or a long axis length, but is not limited thereto.

FIGS. 11A to 11C and FIGS. 12A to 12C will be briefly described.

FIGS. 11A to 11C are first exemplary views of an assembly electrode of a display device 301 including a semiconductor light emitting device according to an embodiment. FIG. 9 can be a cross-sectional view taken along line C1-C2 in the assembly electrode structure shown in FIG. 11C, and the technical features of the embodiment will be described with reference to FIG. 9 together.

Specifically, FIG. 11A is an exemplary view of the first assembled electrode 210 among the assembled electrodes of the display device 301 including the semiconductor light emitting device according to the embodiment.

Next, FIG. 11B is an exemplary view of the second assembled electrode 220 among the assembled electrodes of the display device 301 including the semiconductor light emitting device according to the embodiment.

The second assembly electrode 220 can have an electrode hole 220H in a region overlapping the semiconductor light emitting device 150, so a portion of the insulating layer 212 is exposed.

The size of the electrode hole 220H can be smaller than the size of the semiconductor light emitting device 150. Further, the size of the electrode hole 220H can be smaller than the size of the assembly hole 207H. The size of the electrode hole 220H can be a diameter or a long axis length, but is not limited thereto.

Next, FIG. 11C is an exemplary view in which the second assembly electrode 220 is disposed on the first assembly electrode 210 of the display device 301 including the semiconductor light emitting device according to the embodiment.

Next, FIGS. 12A to 12C are second exemplary views of an assembly electrode of a display device 301 including a semiconductor light emitting device according to an embodiment. FIG. 9 is a cross-sectional view taken along line C1-C2 in the assembly electrode structure shown in FIG. 12C, and the technical features of the embodiment will be described with reference to FIG. 9 together.

Specifically, FIG. 12A is an exemplary view of the first assembled electrode 210 among the assembled electrodes of the display device 301 including the semiconductor light emitting device according to the embodiment.

The first assembly electrode 210 can include a first main electrode 210m and a first protrusion electrode 210p extending therefrom.

Next, FIG. 12B is an exemplary view of the second assembled electrode 220 among the assembled electrodes of the display device 301 including the semiconductor light emitting device according to the embodiment.

The second assembly electrode 220 can include a second main electrode 220m and a second protrusion electrode 220p extended from the second main electrode 220m.

The second main electrode 220m can be disposed parallel in the longitudinal direction of the first main electrode 210m.

The second protrusion electrode 220p can protrude in the direction of the first protrusion electrode 210p, the second protrusion electrode 220p can overlap the first protrusion electrode 210p between the upper and lower sides.

The second protrusion electrode 220p of the second assembly electrode can have an electrode hole 220H in a region overlapping the semiconductor light emitting device 150. A portion of the insulating layer 212 can be exposed. The size of the electrode hole 220H can be smaller than the size of the semiconductor light emitting device 150. The size of the electrode hole 220H can be smaller than the size of the assembly hole 207H. The size of the electrode hole 220H can be a diameter or a long axis length, but is not limited thereto.

Next, FIG. 12C is an exemplary view in which the second assembly electrode 220 is disposed on the first assembly electrode 210 of the display device 301 including the semiconductor light emitting device according to the embodiment.

According to the embodiment, by overlapping between the first protrusion electrode of the first assembly electrode and the second protrusion electrode of the second assembly electrode, the overall overlapping area of the upper electrode and the lower electrode can be reduced and an electric short caused by an opening of an insulating layer and a capacitance between the assembled electrodes can reduced.

Referring back to FIG. 9, in relation to a method of applying an assembly signal to the first assembly electrode 210 and the second assembly electrode 220 in the embodiment, an AC signal can be applied to the first assembled electrode 210 and the second assembled electrode 220.

At this time, the V+/V− signal can be applied to the first assembled electrode 210 which is the lower electrode, and the second assembled electrode 220 which is the upper electrode can be grounded.

According to the embodiment, when V+/V− voltage is applied to the second assembly electrode 220, which is the upper electrode, electricity can occur between the lower electrode of the semiconductor light emitting device 150 and the second assembly electrode 220 of the assembly substrate during LED assembly. Due to this, a voltage drop can occur and the applied voltage can be reduced.

In this case, the more the LED is assembled in the adjacent cell, the more the voltage drop occurs, and the applied voltage to the assembly part decreases, which can weaken the assembly force.

Therefore, the second assembly electrode 220, which is the upper electrode, can be grounded, and V+/V− is applied to the first assembly electrode 210, which is the lower electrode, to prevent a voltage drop, thereby maintaining a high assembly force.

In particular, the reason for grounding the second assembly electrode 220, which is the upper electrode in the present invention, is by acting as an electric field shielding area other than the assembly area, there is a special technical effect to minimize the effect of the semiconductor light emitting device sticking to the barrier wall.

In addition, according to the embodiment, the distribution of the DEP force can be strongly and uniformly distributed at the inner center of the assembly hole through the electric field shielding on the upper side of the assembly hole, and the distribution strength can be controlled weakly on the upper side of the assembly hole. Through this, the semiconductor light emitting device that is not the target of assembling can be prevented from being located on the upper side of the assembly hole, there is a special technical effect that can solve the problem of the screening effect that the entrance to the assembly hall cannot be blocked and the semiconductor light emitting device to be assembled does not enter the assembly hall.

Specifically, FIGS. 10A to 10C are electric field distribution diagrams in assembling a display device 301 including a semiconductor light emitting device according to a comparative example and an embodiment.

First, FIG. 10A is a case in which a horizontal assembly electrode structure according to the first internal technology is employed as a first comparative example (refer to FIG. 7).

According to the E field gradient distribution (Z-axis direction) of FIG. 10A, the E field (log) above the assembly hole of the assembly barrier wall 207 in the first internal technique reaches about 12 (based on log scale).

Next, FIG. 10B is a case in which a vertical asymmetric electrode structure according to the second internal technique is employed as a second comparative example (refer to FIG. 8A).

According to the E field gradient distribution of FIG. 10B, in the second internal technique, the E field (log) on the upper side of the assembly hole of the assembly barrier wall 207 is about 10 (based on log scale), and is about 100 times lower than that of the first internal technique.

Next, FIG. 10C is a case in which a vertical symmetric electrode structure is employed as an embodiment (refer to FIG. 9).

According to the E field gradient distribution of FIG. 10C, the E field (log) on the upper side of the assembly hole of the assembly barrier wall 207 according to the embodiment is about 6 (based on log scale), and is about 10,000 times lower than that of the second internal technology.

Therefore, according to the embodiment, as the V+/V− signal is applied to the lower electrode (the first assembled electrode 210), and the upper electrode (the second assembled electrode 220) can be grounded, it is possible to implement a vertically symmetrical assembly electrode structure having an effect of electrical shielding. Accordingly, the E field gradient around the assembly barrier wall is the smallest, so the distribution of the DEP force is strong and uniformly distributed at the center of the assembly hole, and the strength of the distribution can be controlled weakly on the upper side of the assembly hole.

Finally, according to the embodiment, by preventing the non-assembly target semiconductor light emitting device from being located on the upper side of the assembly hall, the entrance to the assembly hole cannot be blocked, there is a special technical effect that can significantly increase the assembly yield by concentrating the DEP force on the assembly hole to be uniformly assembled by solving the problem of the screening effect.

In addition, according to the embodiment, there is a technical effect in that the lighting rate can be significantly increased due to the improvement of the electrical contact characteristics by increasing the electrical contact area between the bonding metal of the semiconductor light emitting device and the second assembly electrode functioning as a panel electrode.

Referring also to FIGS. 12A to 12C, in the embodiment, by overlapping between the first protrusion electrode of the first assembly electrode and the second protrusion electrode of the second assembly electrode, the overall overlapping area of the upper electrode and the lower electrode can be reduced and an electric short caused by an opening of an insulating layer and a capacitance between the assembled electrodes can reduced.

Accordingly, according to the embodiment, by arranging to overlap between the first protrusion electrode of the first assembly electrode and the second protrusion electrode of the second assembly electrode, defects factors such as electrical short are reduced, there is a complex technical effect that can improve the assembly of the semiconductor light emitting device by allowing the DEP force to be distributed intensively at the center of the assembly hole between the first protrusion electrode and the second protrusion electrode.

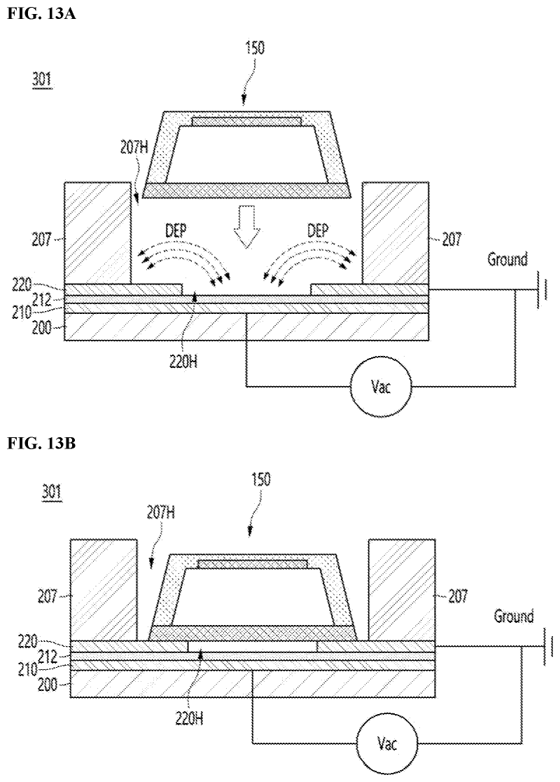

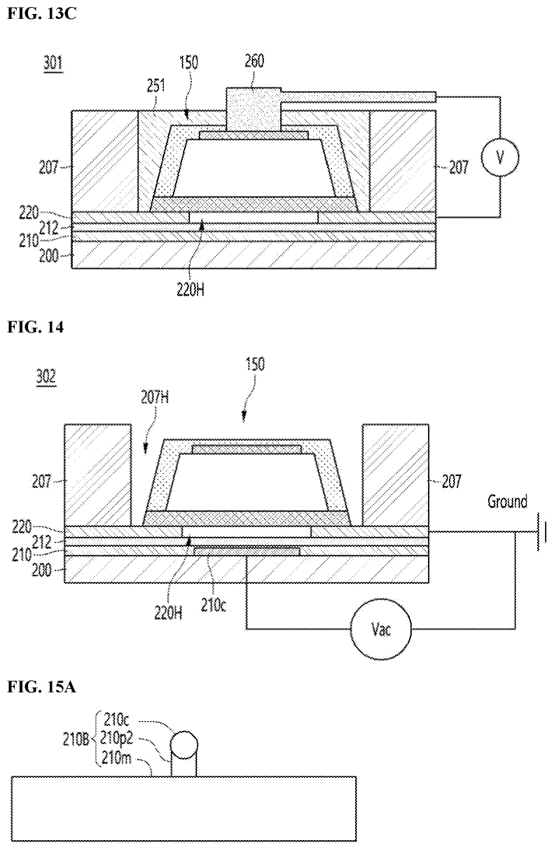

Next, FIGS. 13A to 13C are diagrams illustrating an assembling process of the semiconductor light emitting device 150 using the display device 301 including the semiconductor light emitting device 150 according to the embodiment.

Referring to FIGS. 13A to 13C, according to the semiconductor light emitting device and the display device including the same according to the embodiment, as the first and second assembly electrodes are symmetrically disposed between the top and bottom, a uniform depth of force can be distributed in the center of the assembly hole 207H, and thus, there is a technical effect of improving the assembly rate. A fill material 251 can be located in the assembly hole 207H.

In addition, according to the embodiment, as the V+/V− signal is applied to the first assembled electrode 210 which is the lower electrode, and the second assembled electrode 220 which is the upper electrode, can be grounded, the voltage drop is prevented. Accordingly, there is a special technical effect that can maintain a high assembly force.

In addition, according to the embodiment, the distribution of the DEP force can be strongly and uniformly distributed at the inner center of the assembly hole through the electric field shielding on the upper side of the assembly hole, and the distribution strength can be controlled weakly on the upper side of the assembly hole. Through this, the semiconductor light emitting device that is not the object of assembling is prevented from being located on the upper side of the assembly hole, there is a special technical effect that can solve the problem of the screening effect.

In the embodiment, by increasing the electrical contact area between the electrode of the semiconductor light emitting device and the second assembly electrode 220 functioning as a panel electrode, the electrical contact characteristic is improved, and there is a technical effect of significantly increasing the lighting rate.

In addition, according to the embodiment, there is a technical effect capable of realizing an ultra-high resolution by three-dimensionally disposing the first assembly electrode and the second assembly electrode between the top and bottom.

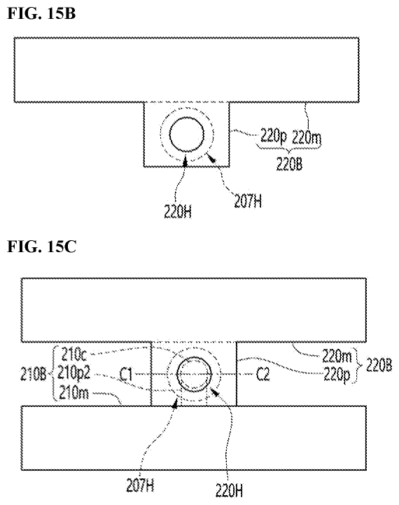

Next, FIG. 14 is a cross-sectional view of a display device 302 having a semiconductor light emitting device according to a second embodiment, and FIG. 15A to 15C are exemplary views of assembled electrodes of the display device 302 including the semiconductor light emitting device according to the second embodiment.

FIG. 14 can be a cross-sectional view taken along line C1-C2 in the assembled electrode structure shown in FIG. 15C.

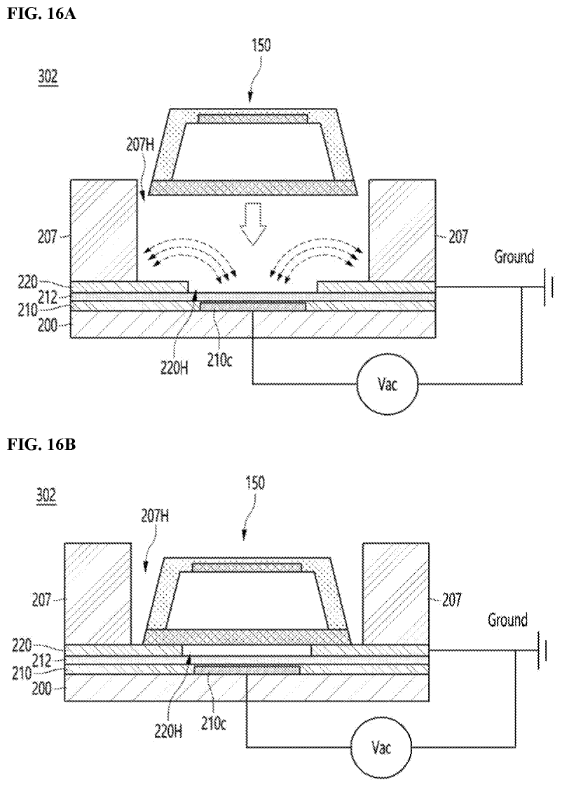

FIGS. 16A to 16B are diagrams illustrating an assembling process of the semiconductor light emitting device 150 using the display device 301 including the semiconductor light emitting device according to the second embodiment.

The second embodiment can adopt the technical features of the first embodiment, and the main features of the second embodiment will be mainly described below.

In the display device 302 including the semiconductor light emitting device according to the second embodiment, the first-second assembly electrode 210B can include the first center electrode 210c overlapping the inside on the upper and lower sides of the electrode hole 220H of the second-second assembly electrode 220B.

Specifically, FIG. 15A is an exemplary view of the first-second assembly electrodes 210B of the display device 302 including the semiconductor light emitting device according to the second embodiment.

The first-second assembly electrode 210B of the second embodiment can include the first main electrode 210m, the first-second protrusion electrode 210p2 extending therefrom, and a first center electrode 210c disposed at the end of the first-second protrusion electrode 210p2.

Next, FIG. 15B is an exemplary view of the second assembly electrode 220 of the display device 302 including the semiconductor light emitting device according to the second embodiment.

The second assembly electrode 220 can include a second main electrode 220m and a second protrusion electrode 220p extended from the second main electrode 220m.

As the second protrusion electrode 220p of the second assembly electrode can have an electrode hole 220H in a region overlapping with the semiconductor light emitting device 150, a portion of the insulating layer 212 can be exposed. The size of the electrode hole 220H can be smaller than the size of the semiconductor light emitting device 150. The size of the electrode hole 220H can be smaller than the size of the assembly hole 207H. The size of the electrode hole 220H can be a diameter or a long axis length, but is not limited thereto.

Next, FIG. 15C is an exemplary view of the second-second assembly electrode 220B is disposed on the first-second assembly electrode 210B of the display device 301 including the semiconductor light emitting device according to the second embodiment.

FIGS. 16A to 16B are diagrams illustrating an assembling process of the semiconductor light emitting device 150 using the display device 302 including the semiconductor light emitting device according to an embodiment.

Referring to FIGS. 16A to 16B, according to the semiconductor light emitting device and the display device including the same according to the second embodiment, the first and second assembly electrodes can be symmetrically disposed between the top and bottom.

In particular, the first-second assembly electrode 210B of the second embodiment can include the first-second protrusion electrode 210p2 extended from the first main electrode 210m and a first center electrode 210c disposed on the end of the first-second protrusion electrode 210p2.

The first center electrode 210c can be disposed to be positioned within an electrode hole 220H provided in the second protrusion electrode 220p of the second assembly electrode.

Through this, according to the second embodiment, the edge between the first center electrode 210c and the second protrusion electrode 220p can be further caused to maximize the Dep force and uniform and strong depth force can be distributed in the assembly hole center, so there is a technical effect that can significantly improve the assembly rate.

In addition, according to the second embodiment, as the V+/V− signal is applied to the first assembled electrode 210 which is the lower electrode, and the second assembled electrode 220 which is the upper electrode can be grounded, the voltage drop can be prevented. Accordingly, there is a special technical effect that can maintain a high assembly force.

In addition, according to the second embodiment, the distribution of the DEP force can be strongly and uniformly distributed at the inner center of the assembly hole through the electric field shielding on the upper side of the assembly hole, and the distribution strength can be controlled weakly on the upper side of the assembly hole. Through this, the semiconductor light emitting device that is not the object of assembly is prevented from being located on the upper side of the assembly hole, there is a special technical effect that can solve the problem of the screening effect.

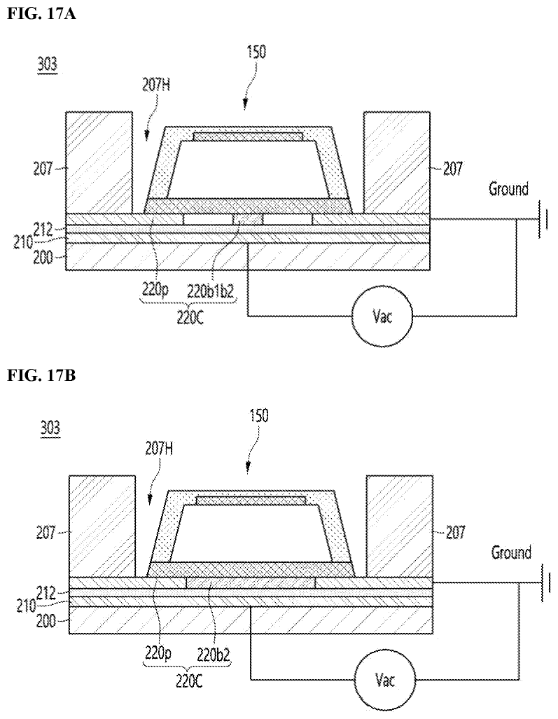

Next, FIG. 17A is a first cross-sectional view of a display device 303 including a semiconductor light emitting device according to a third embodiment, and FIG. 17B is a second cross-sectional view of a display device 303 including a semiconductor light emitting device according to a third embodiment.

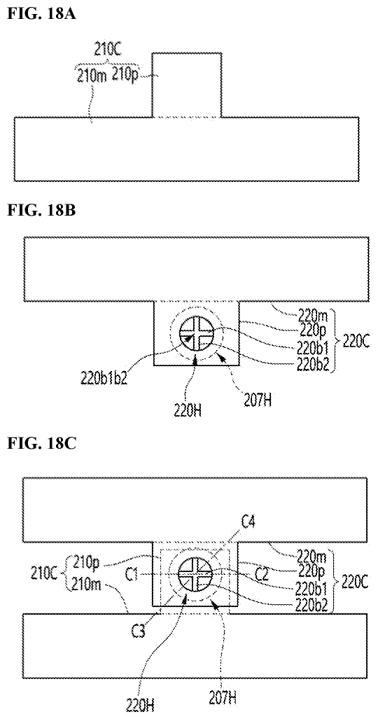

FIGS. 18A to 18C are exemplary views of assembly electrodes of a display device 303 including a semiconductor light emitting device according to a third embodiment.

FIG. 17A is a cross-sectional view taken along line C3-C4 in the assembled electrode structure shown in FIG. 18C. FIG. 17B is a cross-sectional view taken along line C1-C2 in the assembly electrode structure shown in FIG. 18C.

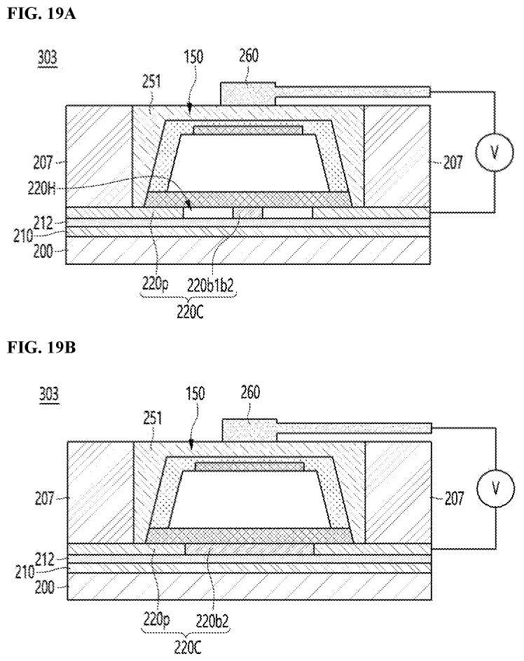

FIGS. 19A to 19B are diagrams illustrating an assembling process of the semiconductor light emitting device 150 using the display device 303 including the semiconductor light emitting device according to an embodiment.

The third embodiment can adopt the technical features of the first or second embodiment, and the main features of the third embodiment will be mainly described below.

In the display device 303 having the semiconductor light emitting device according to the third embodiment, the second-third assembly electrode 220C can include a first bridge electrode 220b1 and a second bridge electrode 220b2 disposed inside the electrode hole 220H of the second-third assembly electrode 220C.

Specifically, FIG. 18A is an exemplary view of first-third assembly electrodes 210C of the display device 302 including the semiconductor light emitting device according to the third embodiment.

The first-third assembly electrodes 210C of the third embodiment can include a first main electrode 210m and a first protrusion electrode 210p extending therefrom.

Next, FIG. 18B is an exemplary view of the second assembly electrode 220C of the display device 303 including the semiconductor light emitting device according to the third embodiment.

The second assembly electrode 220C can include a second main electrode 220m and a second protrusion electrode 220p extended from the second main electrode 220m.

The second protrusion electrode 220p of the second assembly electrode has an electrode hole 220H in a region overlapping the semiconductor light emitting device 150, and has the characteristics to a portion of the insulating layer 212 is exposed. The size of the electrode hole 220H can be smaller than the size of the semiconductor light emitting device 150. The size of the electrode hole 220H can be smaller than the size of the assembly hole 207H. The size of the electrode hole 220H can be a diameter or a long axis length, but is not limited thereto.

At this time, in the display device 303 having the semiconductor light emitting device according to the third embodiment, the 2-3rd assembly electrode 220C is disposed inside the electrode hole 220H and can include a first bridge electrode 220b1 and a second bridge electrode 220b2 connected to each other.

The first bridge electrode 220b1 and the second bridge electrode 220b2 can meet each other at the bridge intersection point 220b1b2.

Next, FIG. 18C is an exemplary view of the second-third assembly electrodes 220C are disposed on the first-third assembly electrode 210C of the display device 303 including the semiconductor light emitting device according to the third embodiment.

FIGS. 19A to 19B are diagrams illustrating an assembling process of the semiconductor light emitting device 150 using the display device 303 including the semiconductor light emitting device according to the third embodiment.

Referring again to FIGS. 17A to 17B, according to the semiconductor light emitting device and the display device including the same according to the third embodiment, the first and second assembly electrodes can be symmetrically disposed between the top and bottom.

In particular, the second-third assembly electrode 220C of the third embodiment is disposed inside the electrode hole 220H of the second-third assembly electrode 220C, and can be included the first bridge electrode 220b1 and the second bridge 220b2 connected to each other. The first bridge electrode 220b1 and the second bridge electrode 220b2 can meet each other at a bridge intersection point 220b1b2.

Through this, according to the third embodiment, there is a technical effect that the lighting rate is further improved by increasing the electrical contact area between the semiconductor light emitting device and the second assembled electrode that can function as an electrode of the panel, thereby improving the electrical contact characteristics.

Further, according to the third embodiment, as the second-third assembly electrode 220C includes the first bridge electrode 220b1 and the second bridge electrode 220b2 disposed inside the electrode hole 220H to further secure an edge region, there is a technical effect that can significantly improve the assembly rate by distributing the dep force uniformly and powerfully in the assembly hole.

In addition, according to the third embodiment, as the V+/V− signal is applied to the first assembled electrode 210 which is the lower electrode, and the second assembled electrode 220 which is the upper electrode is grounded, the voltage drop ca be prevented. Accordingly, there is a special technical effect that can maintain a high assembly force.

In addition, according to the third embodiment, the distribution of the DEP force can be strongly and uniformly distributed at the inner center of the assembly hole through the electric field shielding on the upper side of the assembly hole, and the distribution strength can be controlled weakly on the upper side of the assembly hole. Through this, the semiconductor light emitting device that is not the object of assembly is prevented from being located on the upper side of the assembly hole, there is a special technical effect that can solve the problem of the screening effect.

The above detailed description should not be construed as limiting in all respects, but should be considered as exemplary. The scope of the embodiments should be determined by a reasonable interpretation of the appended claims, and all modifications within the equivalent scope of the embodiments are included in the scope of the embodiments.

### INDUSTRIAL APPLICABILITY

The embodiment can be employed in the field of display for displaying images or information.

The embodiment can be applied to a display field for displaying an image or information using a semiconductor light emitting device.

The embodiment can be employed in the display field for displaying images or information using micro- or nano-level semiconductor light emitting devices.

What is claimed is:

1. A display device comprising:
a first assembly electrode disposed on a substrate;
a second assembly electrode disposed on the first assembly electrode;
an insulating layer disposed between the first assembly electrode and the second assembly electrode;
an assembly barrier wall including an assembly hole and disposed on the second assembly electrode; and
a semiconductor light emitting device disposed in the assembly hole and electrically connected to the second assembly electrode,
wherein the second assembly electrode comprises an electrode hole in a region overlapping the semiconductor light emitting device, and the electrode hole exposes a portion of the insulating layer.

2. The display device according to claim 1, wherein a size of the electrode hole is less than a size of the semiconductor light emitting device.

3. The display device according to claim 1, wherein an alternating current (AC) power is applied to the first assembly electrode, and
wherein the second assembly electrode is grounded.

4. The display device according to claim 1, wherein the first assembly electrode comprises a first main electrode and a first protrusion electrode extended from the first main electrode.

5. The display device according to claim 4, wherein the second assembly electrode comprises a second main electrode disposed parallel in a longitudinal direction of the first main electrode and a second protrusion electrode extended from the second main electrode.

6. The display device according to claim 5, wherein the second protrusion electrode protrudes toward the first protrusion electrode.

7. The display device according to claim 6, wherein the second protrusion electrode overlaps the first protrusion electrode in a vertical direction.

8. The display device according to claim 7, wherein the second protrusion electrode of the second assembly electrode comprises the electrode hole in the region overlapping the semiconductor light emitting device that exposes the portion of the insulating layer.

9. The display device according to claim 5, wherein the first assembly electrode comprises a first center electrode overlapping an inside of the electrode hole of the second protrusion electrode in a vertical direction.

10. The display device according to claim 1, wherein the second assembly electrode comprises a first bridge electrode and a second bridge electrode disposed inside the electrode hole and connected to each other.

11. A display device comprising:
a first assembly electrode disposed on a substrate;
a second assembly electrode disposed on the first assembly electrode;
an insulating layer disposed between the first assembly electrode and the second assembly electrode;
an assembly barrier wall including an assembly hole and disposed on the second assembly electrode; and
a semiconductor light emitting device disposed in the assembly hole and electrically connected to the second assembly electrode,
wherein the first assembly electrode comprises a first main electrode and a first protrusion electrode extended from the first main electrode.

12. The display device according to claim 11, wherein the second assembly electrode comprises an electrode hole in a region overlapping the semiconductor light emitting device, and the electrode hole exposes a portion of the insulating layer.

13. The display device according to claim 12, wherein a size of the electrode hole is less than a size of the semiconductor light emitting device.

14. The display device according to claim 11, wherein an alternating current (AC) power is applied to the first assembly electrode, and
wherein the second assembly electrode is grounded.

15. The display device according to claim 11, wherein the second protrusion electrode protrudes toward the first protrusion electrode.

16. The display device according to claim 15, wherein the second protrusion electrode overlaps the first protrusion electrode in a vertical direction.

17. A display device comprising:
a first assembly electrode disposed on a substrate;
a second assembly electrode disposed on the first assembly electrode;
an insulating layer disposed between the first assembly electrode and the second assembly electrode;
an assembly barrier wall including an assembly hole and disposed on the second assembly electrode; and
a semiconductor light emitting device disposed in the assembly hole and electrically connected to the second assembly electrode,
wherein an alternating current (AC) power is applied to the first assembly electrode, and the second assembly electrode is grounded.

18. The display device according to claim 17, wherein the first assembly electrode comprises a first main electrode and a first protrusion electrode extended from the first main electrode.

19. The display device according to claim 17, wherein the second assembly electrode comprises an electrode hole in a region overlapping the semiconductor light emitting device, and the electrode hole exposes a portion of the insulating layer, and
wherein a distribution of a dielectrophoresis (DEP) force is uniform at an inner center of the assembly hole through an electric field shielding on an upper side of the assembly hole, and a distribution strength of the DEP force is controlled on the upper side of the assembly.

20. The display device according to claim 17, wherein the first assembly electrode comprises a first center electrode overlapping an inside of the electrode hole of the second protrusion electrode in a vertical direction.
